(19) United States
(12) Patent Application Publication
(10) Pub. No.: US 2025/0359063 A1
(43) Pub. Date: Nov. 20, 2025

(54) TRANSISTOR WITH CHANNEL LAYER INCLUDING HEAVILY DOPED REGION

(71) Applicant: MICRON TECHNOLOGY, INC., BOISE, ID (US)

(72) Inventors: Albert Fayrushin, Boise, ID (US); Naveen Kaushik, Boise, ID (US); Haitao Liu, Boise, ID (US); Jun Fujiki, Tokyo (JP)

(73) Assignee: MICRON TECHNOLOGY, INC., BOISE, ID (US)

(21) Appl. No.: 19/181,421

(22) Filed: Apr. 17, 2025

Related U.S. Application Data
(60) Provisional application No. 63/637,937, filed on Apr. 24, 2024.

(51) Int. Cl. H10B 43/40; G11C 16/08; H10B 41/41

(52) U.S. Cl. CPC H10B 43/40; G11C 16/08; H10B 41/41

(57) ABSTRACT

A transistor includes a source, a drain, a gate layer, an undoped or lightly doped channel layer, and a gate dielectric layer. The undoped or lightly doped channel layer extends between the source and the drain. The channel layer includes at least one heavily doped region to distribute channel potential along the channel layer. The gate dielectric layer is between the gate layer and the channel layer.

### RELATED APPLICATION

This application claims the benefit of U.S. Provisional Application No. 63/637,937, filed on Apr. 24, 2024, hereby incorporated herein in its entirety by reference.

### TECHNICAL FIELD

The present disclosure relates generally to transistors and, in particular, in one or more embodiments, the present disclosure relates to improving the breakdown voltage of silicon-on-insulator (SOI) transistors or thin-film transistors (TFTs).

### BACKGROUND

Transistors made on bulk silicon might include a source and/or a drain with an extended lightly doped drain (LDD) region to improve the breakdown voltage of the transistors. The breakdown voltage of the transistors may be dependent upon the length of the transistors. Silicon-on-insulator (SOI) transistors or thin-film transistors (TFTs) may not include extended LDD regions, which reduces the breakdown voltage of the SOI transistors or TFTs compared to bulk silicon transistors.

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Each access line is biased during NAND flash memory cell programming by an access line driver, which may include a SOI transistor. Columns of the array include strings (often termed NAND strings) of memory cells connected together in series between a pair of select gates, e.g., a source select transistor and a drain select transistor. Each source select transistor may be connected to a source, while each drain select transistor may be connected to a data line, such as a column bit line. Variations using more than one select gate between a string of memory cells and the source, and/or between the string of memory cells and the data line, are known.

### BRIEF DESCRIPTION OF THE DRAWINGS

FIGS. 1A and 1B depict a transistor according to an embodiment.

FIG. 1C depicts a transistor according to another embodiment.

FIG. 2 depicts a device including the transistor of FIG. 1 according to an embodiment.

FIG. 3 depicts a transistor according to another embodiment.

FIGS. 4A and 4B depict a transistor according to another embodiment.

FIGS. 5A and 5B depict a transistor according to another embodiment.

FIGS. 6A and 6B depict a transistor according to another embodiment.

FIG. 6C depicts a transistor according to another embodiment.

FIGS. 7A and 7B depict a transistor according to another embodiment.

FIG. 8 is a simplified block diagram of a memory in communication with a processor as part of an electronic system, according to an embodiment.

FIGS. 9A and 9B are schematics of portions of an array of memory cells as could be used in a memory of the type described with reference to FIG. 8.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments may be utilized and structural, logical and electrical changes may be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin-film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting unless otherwise apparent from the context.

Ranges might be expressed herein as from “about” one particular value, and/or to “about” another particular value. When such a range is expressed, another embodiment might include from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

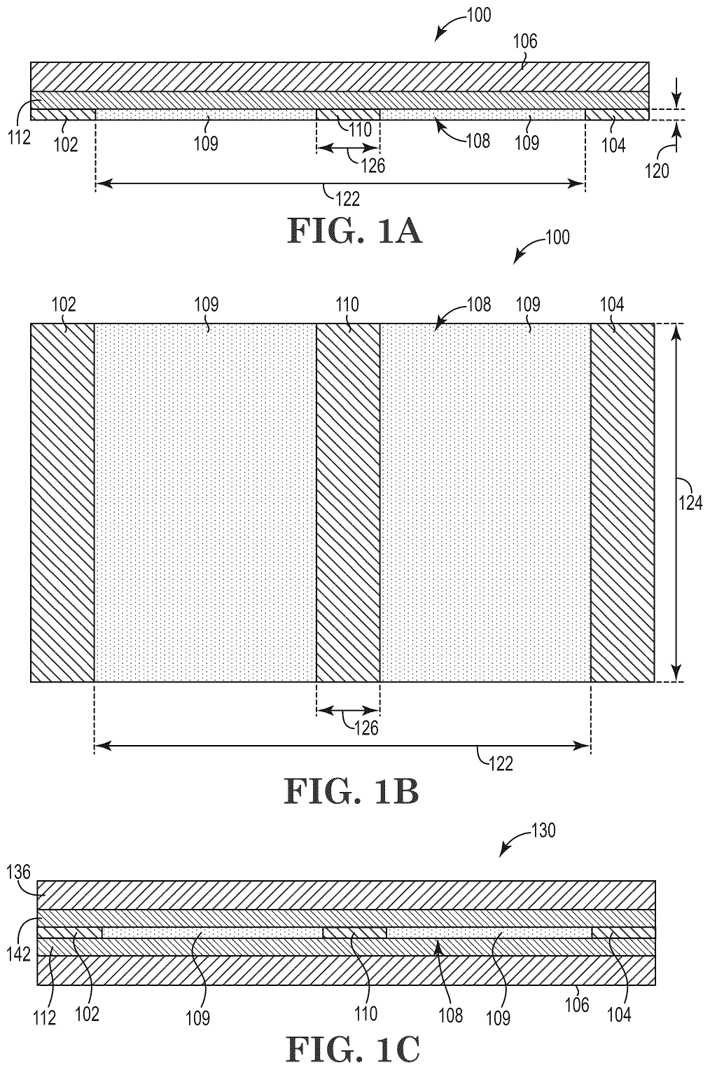

FIG. 1A is a cross-sectional view and FIG. 1B is a bottom view depicting a transistor 100 according to an embodiment. Transistor 100 may be a SOI transistor or a TFT. Transistor 100 includes a source 102 (e.g., a heavily doped semiconductor material region), a drain 104 (e.g., a heavily doped semiconductor material region), a gate layer 106 (e.g., a metal layer or polysilicon layer), a channel layer 108, and a gate dielectric layer 112 (e.g., a metal oxide layer or nitride layer). Gate dielectric layer 112 is between the gate layer 106 and the channel layer 108. Transistor 100 may be formed along any axis within a device, such as along a horizontal axis or a vertical axis.

Channel layer 108 includes regions 109 and at least one heavily doped region 110. Channel layer 108 includes an undoped or lightly doped semiconductor material in regions 109 and extends between the source 102 and the drain 104. The at least one heavily doped region 110 distributes channel potential along the channel layer 108 to improve the breakdown voltage of the transistor 100 compared to a transistor not including the at least one heavily doped region 110. While transistor 100 includes one heavily doped region 110 in FIGS. 1A and 1B, in other examples, transistor 100 might include more than one heavily doped region 110 (e.g., 2, 3, 4, 5, 6, 7, 8, 9, 10, or more spaced apart heavily doped regions 110). While the at least one heavily doped region 110 is illustrated as being in the center of the channel layer 108 in FIGS. 1A and 1B, in other examples, the at least one heavily doped region 110 may be offset from the center of the channel layer 108. The position and number of heavily doped regions 110 within transistor 100 may be selected to provide a desired channel potential distribution across a length 122 of the channel layer 108.

As illustrated in FIG. 1A, the at least one heavily doped region 110 extends completely through a thickness 120 of the channel layer 108. As illustrated in FIG. 1B, the at least one heavily doped region 110 extends completely across a width 124 of the channel layer 108. In one embodiment, the at least one heavily doped region 110 includes an N+ doped region and the transistor 100 includes an N-type transistor, such that the source 102 and the drain 104 are N+ doped regions. In another embodiment, the at least one heavily doped region 110 includes a P+ doped region and the transistor includes a P-type transistor, such that the source 102 and the drain 104 are P+ doped regions. In some examples, the length 122 of the channel layer 108 may be within a range between about 0.1 micrometers and about 10 micrometers, the width 124 of the channel layer 108 may be within a range between about 0.1 micrometers and about 100 micrometers, and the thickness 120 of the channel layer 108 may be within a range between about 1 nanometer and about 100 nanometers. A length 126 of the at least one heavily doped region 110 may be within a range between about 10 nanometers and about 500 nanometers. In other examples, the length 122, the width 124, and the thickness 120 of the channel layer 108 and the length 126 of the at least one heavily doped region 110 may have other suitable values.

The channel layer 108 might include at least one of a polysilicon layer, a silicon layer, a germanium layer, a silicon-germanium (SiGe) layer, a molybdenum disulfide (MoS₂) layer, a two-dimensional semiconductor layer, or another suitable semiconductor material layer. In some embodiments, the at least one heavily doped region 110 (and the source 102 and the drain 104) might be formed by ion implantation of the semiconductor layer through a mask. In some embodiments, regions 109 of the channel layer 108 might include a first semiconductor material and the at least one heavily doped region 110 might include a second semiconductor material different from the first semiconductor material. In these embodiments, the at least one heavily doped region 110 might include a second semiconductor material inserted into the channel layer 108 via in-situ deposition of the second material. For example, regions 109 of the channel layer 108 might include polysilicon and the at least one heavily doped region 110 might include germanium. In embodiments using different semiconductor materials for regions 109 and the at least one heavily doped region 110, band-to-band generation at the boundary between the regions 109 and the at least one heavily doped region 110 may be enhanced when the transistor 100 is turned off (e.g., not conducting), resulting in a faster channel potential redistribution.

FIG. 1C is a cross-sectional view depicting a transistor 130 according to another embodiment. Transistor 130 is similar to transistor 100 previously described and illustrated with reference to FIGS. 1A and 1B, except that transistor 130 includes a double gate structure. Transistor 130 includes a source 102, a drain 104, a gate layer 106, a channel layer 108, and a gate dielectric layer 112 as previously described. In addition, transistor 130 includes a further gate layer 136 opposite gate layer 106 and a further gate dielectric layer 142 opposite gate dielectric layer 112. Gate dielectric layer 142 is between the gate layer 136 and the channel layer 108.

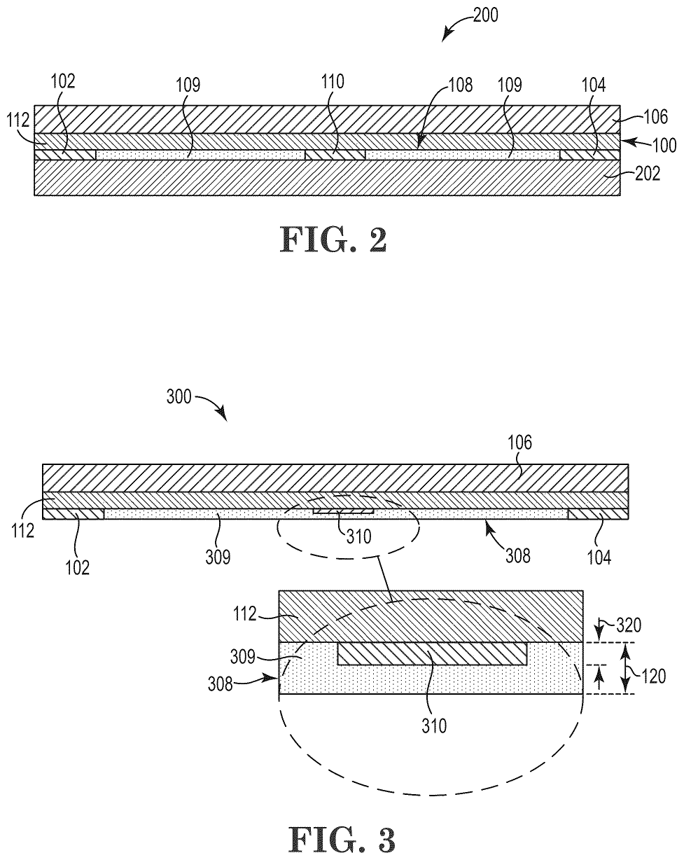

FIG. 2 depicts a cross-sectional view of a device 200 including the transistor 100 of FIG. 1 according to an embodiment. Device 200 includes a substrate 202, on which transistor 100 is formed. In one example, substrate 202 might include a SOI substrate such that transistor 100 is a SOI transistor. In another example, substrate 202 might include a dielectric material substrate (e.g., glass, ceramic, polymer, etc.) such that transistor 100 is a TFT. While the device 200 illustrated in FIG. 2 includes one transistor 100, in other embodiments, device 200 may include any suitable number of transistors 100 and/or other circuitry electrically coupled to the transistor(s) 100.

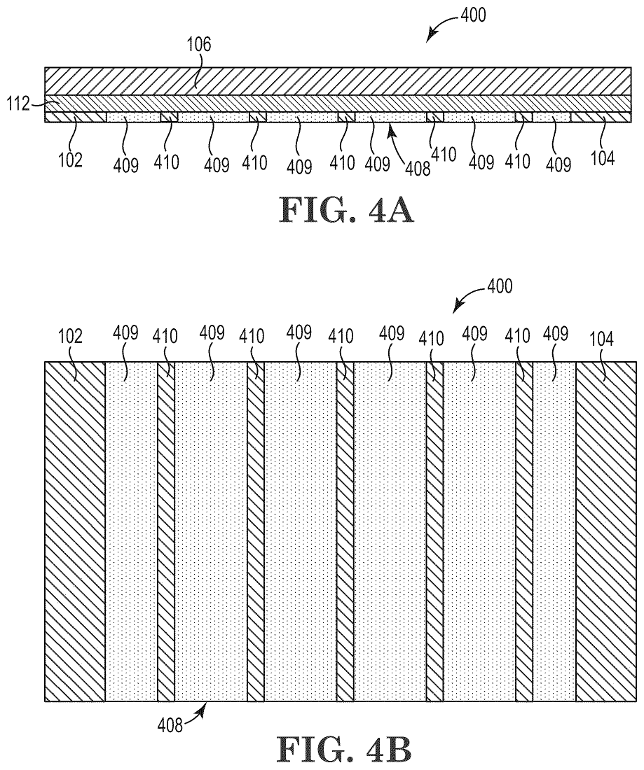

FIG. 3 depicts a cross-sectional view of a transistor 300 according to another embodiment including an enlarged portion indicated by dashed lines. Transistor 300 may be a SOI transistor or a TFT. Transistor 300 includes a source 102, a drain 104, a gate layer 106, a channel layer 308, and a gate dielectric layer 112. Gate dielectric layer 112 is between the gate layer 106 and the channel layer 308.

Channel layer 308 includes a region 309 and at least one heavily doped region 310. Channel layer 308 includes undoped or lightly doped semiconductor material in region 309 and extends between the source 102 and the drain 104. The at least one heavily doped region 310 distributes channel potential along the channel layer 308 to improve the breakdown voltage of the transistor 300 compared to a transistor not including the at least one heavily doped region 310. While transistor 300 includes one heavily doped region 310 in FIG. 3, in other examples, transistor 300 might include more than one heavily doped region 310 (e.g., 2, 3, 4, 5, 6, 7, 8, 9, 10, or more spaced apart heavily doped regions 310). While the at least one heavily doped region 310 is illustrated as being in the center of the channel layer 308 in FIG. 3, in other examples, the at least one heavily doped region 310 may be offset from the center of the channel layer 308. The position and number of heavily doped regions 310 within transistor 300 may be selected to provide a desired channel potential distribution across the length of the channel layer 308.

As illustrated in FIG. 3, the at least one heavily doped region 310 extends partially through (e.g., not completely through) the thickness 120 of the channel layer 308. Accordingly, a thickness 320 of the heavily doped region 310 is less than the thickness 120 of the channel layer 308. In some examples, the thickness 320 of the heavily doped region 310 might be at least about 25 percent of the thickness 120, at least about 50 percent of the thickness 120, or at least about 75 percent of the thickness 120 of the channel layer 308. In some examples, the heavily doped region 310 may extend from a top surface of the channel layer 308 contacting the gate dielectric layer 112 into region 309 of the channel layer 308 toward the bottom surface of the channel layer 308.

In one embodiment, the at least one heavily doped region 310 includes an N+ doped region and the transistor 300 includes an N-type transistor, such that the source 102 and the drain 104 are N+ doped regions. In another embodiment, the at least one heavily doped region 310 includes a P+ doped region and the transistor 300 includes a P-type transistor, such that the source 102 and the drain 104 are P+ doped regions. The length, width, and thickness of the channel layer 308 of transistor 300 might be similar to the length, width, and thickness of the channel layer 108 of transistor 100 previously described and illustrated with reference to FIGS. 1A and 1B. The length and width of the at least one heavily doped region 310 of transistor 300 might be similar to the length and width of the at least one heavily doped region 110 of transistor 100 previously described and illustrated with reference to FIGS. 1A and 1B.

The channel layer 308 might include at least one of a polysilicon layer, a silicon layer, a germanium layer, a silicon-germanium (SiGe) layer, a molybdenum disulfide (MoS₂) layer, a two-dimensional semiconductor layer, or another suitable semiconductor material layer. In some embodiments, the at least one heavily doped region 310 (and the source 102 and the drain 104) might be formed by ion implantation of the semiconductor layer through a mask. In some embodiments, region 309 of the channel layer 308 might include a first semiconductor material and the at least one heavily doped region 310 might include a second semiconductor material different from the first semiconductor material. In these embodiments, the at least one heavily doped region 310 might include a second semiconductor material inserted into the channel layer 308 via in-situ deposition of the second material. For example, region 309 of the channel layer 308 might include polysilicon and the at least one heavily doped region 310 might include germanium. In embodiments using different semiconductor materials for region 309 and the at least one heavily doped region 310, band-to-band generation at the boundary between the region 309 and the at least one heavily doped region 310 may be enhanced when the transistor 300 is turned off (e.g., not conducting), resulting in a faster channel potential redistribution.

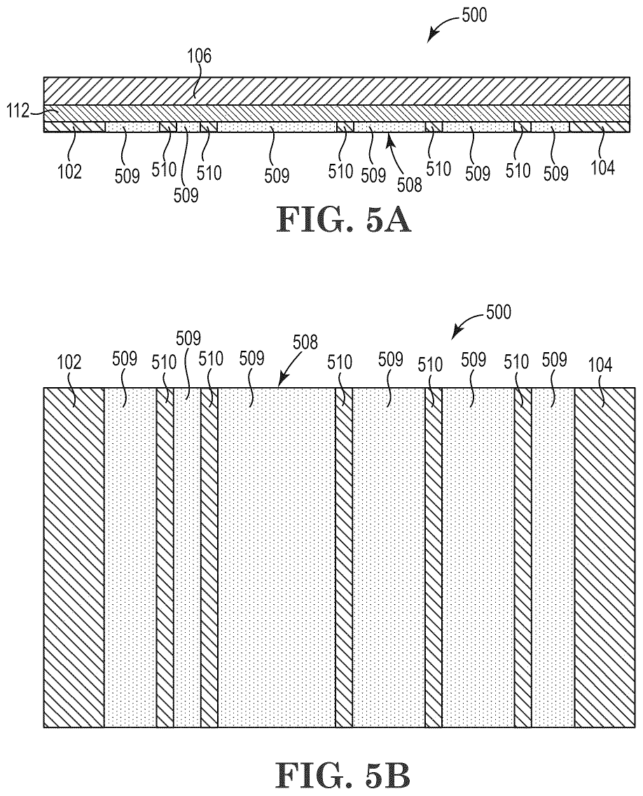

FIG. 4A is a cross-sectional view and FIG. 4B is a bottom view depicting a transistor 400 according to another embodiment. Transistor 400 may be a SOI transistor or a TFT. Transistor 400 includes a source 102, a drain 104, a gate layer 106, a channel layer 408, and a gate dielectric layer 112. Gate dielectric layer 112 is between the gate layer 106 and the channel layer 408.

Channel layer 408 includes regions 409 and a plurality of heavily doped regions 410. Channel layer 408 includes undoped or lightly doped semiconductor material in regions 409 and extends between the source 102 and the drain 104. The plurality of heavily doped regions 410 distribute channel potential along the channel layer 408 to improve the breakdown voltage of the transistor 400 compared to a transistor not including the plurality of heavily doped regions 410. In this embodiment, the plurality of heavily doped regions 410 are evenly spaced apart along the channel layer 408. While five heavily doped regions 410 are illustrated in FIGS. 4A and 4B, in other examples, the plurality of heavily doped regions 410 may include less than five (e.g., 1, 2, 3, or 4) heavily doped regions or more than five (e.g., 6, 7, 8, 9, 10, or more) heavily doped regions. The number of heavily doped regions 410 within transistor 400 may be selected to provide a desired channel potential distribution across the length of the channel layer 408. While each of the plurality of heavily doped regions 410 is illustrated as extending completely through the thickness of the channel layer 408 in FIG. 4A, in other examples, a single heavily doped region 410, a subset of the plurality of heavily doped regions 410, or all of the plurality of heavily doped regions 410 might extend partially through the thickness of the channel layer 408 similar to heavily doped region 310 previously described and illustrated with reference to FIG. 3.

In one embodiment, the plurality of heavily doped regions 410 each include an N+ doped region and the transistor 400 includes an N-type transistor, such that the source 102 and the drain 104 are N+ doped regions. In another embodiment, the plurality of heavily doped regions 410 each include a P+ doped region and the transistor 400 includes a P-type transistor, such that the source 102 and the drain 104 are P+ doped regions. The length, width, and thickness of the channel layer 408 of transistor 400 might be similar to the length, width, and thickness of the channel layer 108 of transistor 100 previously described and illustrated with reference to FIGS. 1A and 1B. The length and width of each of the plurality of heavily doped regions 410 of transistor 400 might be similar to the length and width of the at least one heavily doped region 110 of transistor 100 previously described and illustrated with reference to FIGS. 1A and 1B. While the length of each of the plurality of heavily doped regions 410 is illustrated in FIGS. 4A and 4B as being equal, in other embodiments, the lengths of the plurality of heavily doped regions 410 may be different.

The channel layer 408 might include at least one of a polysilicon layer, a silicon layer, a germanium layer, a silicon-germanium (SiGe) layer, a molybdenum disulfide (MoS₂) layer, a two-dimensional semiconductor layer, or another suitable semiconductor material layer. In some embodiments, the plurality of heavily doped regions 410 (and the source 102 and the drain 104) might be formed by ion implantation of the semiconductor layer through a mask. In some embodiments, regions 409 of the channel layer 408 might include a first semiconductor material and the plurality of heavily doped regions 410 might include a second semiconductor material different from the first semiconductor material. In these embodiments, the plurality of heavily doped regions 410 might include a second semiconductor material inserted into the channel layer 408 via in-situ deposition of the second material. For example, regions 409 of the channel layer 408 might include polysilicon and the plurality of heavily doped regions 410 might include germanium. In embodiments using different semiconductor materials for regions 409 and the plurality of heavily doped regions 410, band-to-band generation at the boundaries between the regions 409 and the plurality of heavily doped regions 410 may be enhanced when the transistor 400 is turned off (e.g., not conducting), resulting in a faster channel potential redistribution.

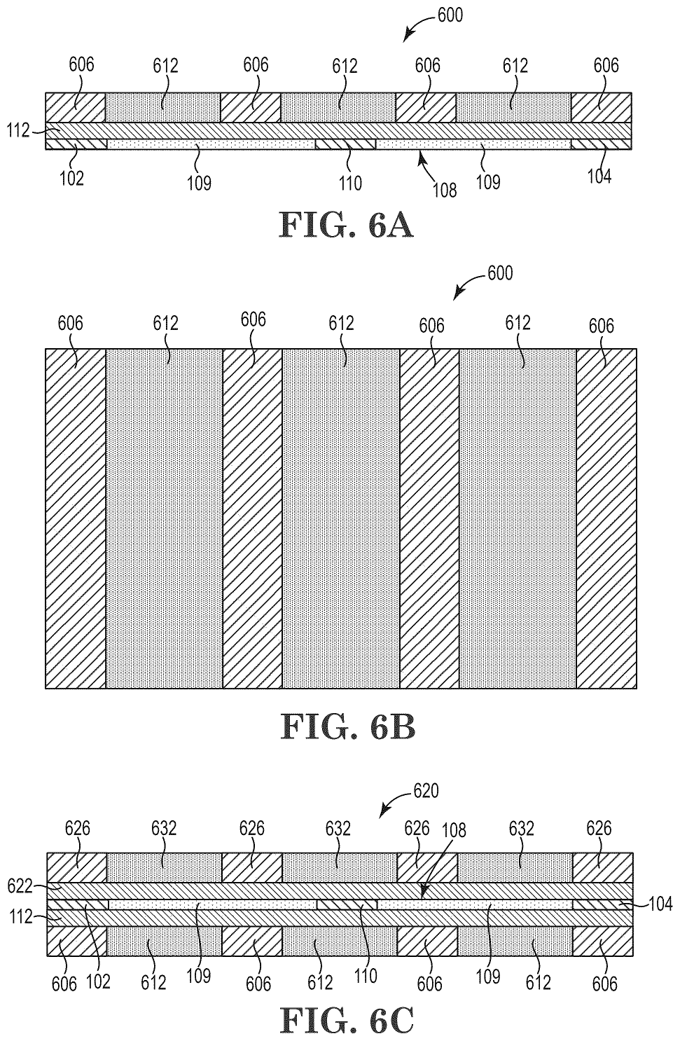

FIG. 5A is a cross-sectional view and FIG. 5B is a bottom view depicting a transistor 500 according to another embodiment. Transistor 500 may be a SOI transistor or a TFT. Transistor 500 includes a source 102, a drain 104, a gate layer 106, a channel layer 508, and a gate dielectric layer 112. Gate dielectric layer 112 is between the gate layer 106 and the channel layer 508.

Channel layer 508 includes regions 509 and a plurality of heavily doped regions 510. Channel layer 508 includes undoped or lightly doped semiconductor material in regions 509 and extends between the source 102 and the drain 104. The plurality of heavily doped regions 510 distribute channel potential along the channel layer 508 to improve the breakdown voltage of the transistor 500 compared to a transistor not including the plurality of heavily doped regions 510. In this embodiment, the plurality of heavily doped regions 510 are unevenly spaced apart along the channel layer 508. While five heavily doped regions 510 are illustrated in FIGS. 5A and 5B, in other examples, the plurality of heavily doped regions 510 may include less than five (e.g., 1, 2, 3, or 4) heavily doped regions or more than five (e.g., 6, 7, 8, 9, 10, or more) heavily doped regions. The position and number of heavily doped regions 510 within transistor 500 may be selected to provide a desired channel potential distribution across a length of the channel layer 508. While each of the plurality of heavily doped regions 510 is illustrated as extending completely through the thickness of the channel layer 508 in FIG. 5A, in other examples, a single heavily doped region 510, a subset of the plurality of heavily doped regions 510, or all of the plurality of heavily doped regions 510 might extend partially through the thickness of the channel layer 508 similar to heavily doped region 310 previously and illustrated described with reference to FIG. 3.

In one embodiment, the plurality of heavily doped regions 510 each include an N+ doped region and the transistor 500 includes an N-type transistor, such that the source 102 and the drain 104 are N+ doped regions. In another embodiment, the plurality of heavily doped regions 510 each include a P+ doped region and the transistor 500 includes a P-type transistor, such that the source 102 and the drain 104 are P+ doped regions. The length, width, and thickness of the channel layer 508 of transistor 500 might be similar to the length, width, and thickness of the channel layer 108 of transistor 100 previously described and illustrated with reference to FIGS. 1A and 1B. The length and width of each of the plurality of heavily doped regions 510 of transistor 500 might be similar to the length and width of the at least one heavily doped region 110 of transistor 100 previously described and illustrated with reference to FIGS. 1A and 1B. While the length of each of the plurality of heavily doped regions 510 is illustrated in FIGS. 5A and 5B as being equal, in other embodiments, the lengths of the plurality of heavily doped regions 510 may be different.

The channel layer 508 might include at least one of a polysilicon layer, a silicon layer, a germanium layer, a silicon-germanium (SiGe) layer, a molybdenum disulfide (MoS₂) layer, a two-dimensional semiconductor layer, or another suitable semiconductor material layer. In some embodiments, the plurality of heavily doped regions 510 (and the source 102 and the drain 104) might be formed by ion implantation of the semiconductor layer through a mask. In some embodiments, regions 509 of the channel layer 508 might include a first semiconductor material and the plurality of heavily doped regions 510 might include a second semiconductor material different from the first semiconductor material. In these embodiments, the plurality of heavily doped regions 510 might include a second semiconductor material inserted into the channel layer 508 via in-situ deposition of the second material. For example, regions 509 of the channel layer 508 might include polysilicon and the plurality of heavily doped regions 510 might include germanium. In embodiments using different semiconductor materials for regions 509 and the plurality of heavily doped regions 510, band-to-band generation at the boundaries between the regions 509 and the plurality of heavily doped regions 510 may be enhanced when the transistor 500 is turned off (e.g., not conducting), resulting in a faster channel potential redistribution.

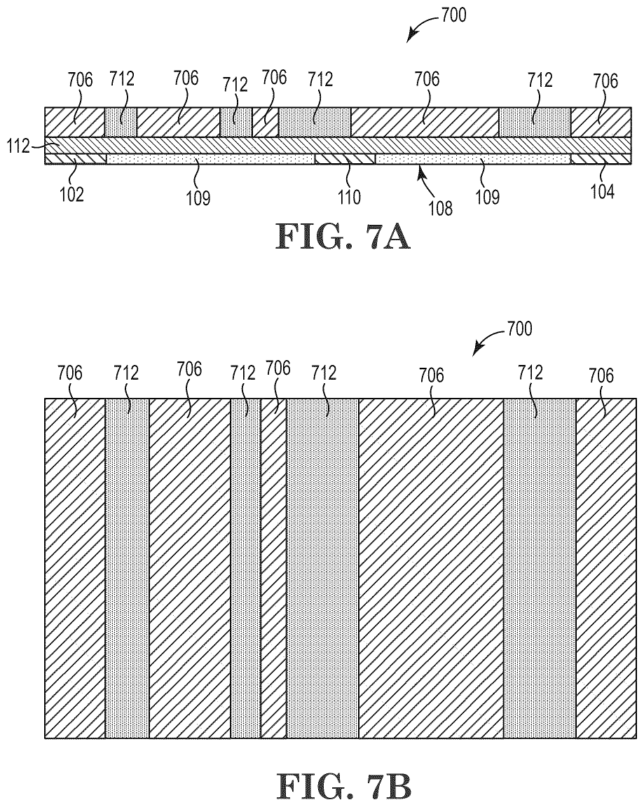

FIG. 6A is a cross-sectional view and FIG. 6B is a top view depicting a transistor 600 according to another embodiment. Transistor 600 may be a SOI transistor or a TFT. Transistor 600 includes a source 102, a drain 104, a gate layer including a plurality of spaced apart gate segments 606 (e.g., metal segments or polysilicon segments), a channel layer 108, and a gate dielectric layer 112. Channel layer 108 includes regions 109 and at least one heavily doped region 110 as previously described and illustrated with reference to FIGS. 1A and 1B. Gate dielectric layer 112 is between the gate layer (e.g., plurality of spaced apart gate segments 606) and the channel layer 108. Dielectric material 612 (e.g., metal oxide or nitride) might be arranged between the gate segments 606. As illustrated in FIG. 6B, each of the plurality of gate segments 606 might extend completely across the width of the transistor 600.

In this embodiment, the plurality of spaced apart gate segments 606 are evenly spaced apart along the length of the transistor 600 (and along the length of the channel layer 108), and each of the plurality of spaced apart gate segment 606 have the same length. While four gate segments 606 are illustrated in FIGS. 6A and 6B, in other examples, the plurality of gate segments 606 may include less than four (e.g., 2, 3) gate segments or more than four (e.g., 5, 6, 7, 8, 9, 10, or more) gate segments. While the at least one heavily doped region 110 is illustrated in FIG. 6A, in other examples, transistor 600 may include the at least one heavily doped region 310 of FIG. 3, the plurality of heavily doped regions 410 of FIGS. 4A and 4B, or the plurality of heavily doped regions 510 of FIGS. 5A and 5B.

Each gate segment 606 may be biased with a different gate bias to turn off transistor 600 to distribute, in combination with the at least one heavily doped region 110, the channel potential along the channel layer 108 to improve the breakdown voltage of the transistor 600 compared to a transistor including a single gate (e.g., 106 of FIGS. 1A-5B). The bias applied to each gate segment may gradually increase from the lower voltage side of the transistor (e.g., one of source 102 or drain 104) towards the higher voltage side of the transistor (e.g., the other one of source 102 or drain 104). The position and number of gate segments 606 (and the bias applied to each gate segment) and the position and number of heavily doped regions 110 may be selected to provide a desired channel potential distribution across the length of the channel layer 108.

FIG. 6C is a cross-sectional view depicting a transistor 620 according to another embodiment. Transistor 620 is similar to transistor 600 previously described and illustrated with reference to FIGS. 6A and 6B, except that transistor 620 includes a double gate structure. Transistor 620 includes a source 102, a drain 104, a gate layer including a plurality of spaced apart gate segments 606, a channel layer 108, and a gate dielectric layer 112 as previously described. In addition, transistor 620 includes a further gate layer including a plurality of spaced apart gate segments 626 opposite the gate layer including the plurality of spaced apart gate segments 606 and a further gate dielectric layer 622 opposite gate dielectric layer 112. Gate dielectric layer 622 is between the further gate layer (e.g., plurality of spaced apart gate segments 626) and the channel layer 108. Dielectric material 632 (e.g., metal oxide or nitride) might be arranged between the gate segments 626.

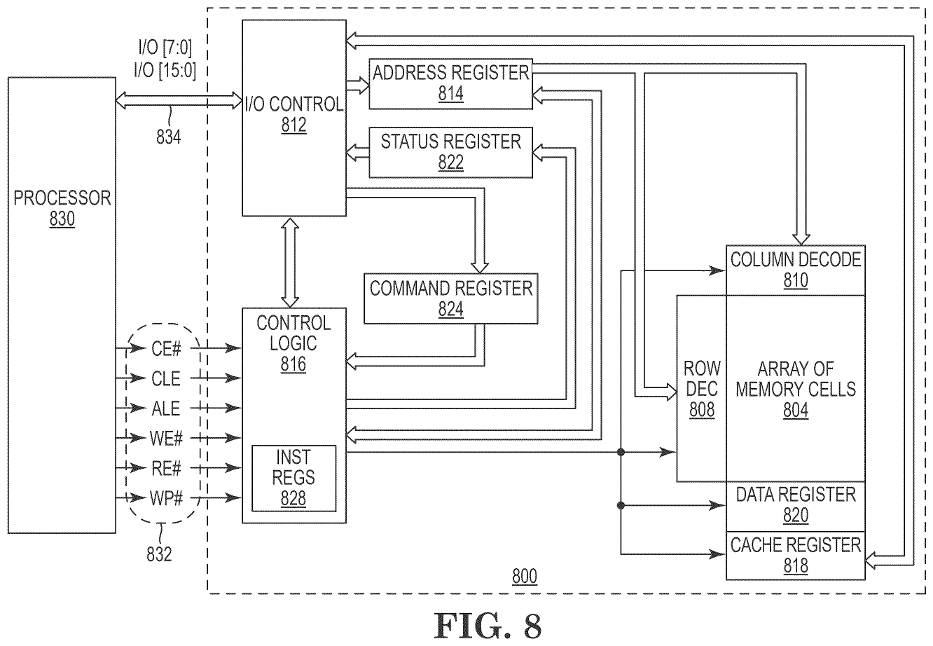

FIG. 7A is a cross-sectional view and FIG. 7B is a top view depicting a transistor 700 according to another embodiment. Transistor 700 may be a SOI transistor or a TFT. Transistor 700 includes a source 102, a drain 104, a gate layer including a plurality of spaced apart gate segments 706 (e.g., metal segments or polysilicon segments), a channel layer 108, and a gate dielectric layer 112. Channel layer 108 includes regions 109 and at least one heavily doped region 110 as previously described and illustrated with reference to FIGS. 1A and 1B. Gate dielectric layer 112 is between the gate layer (e.g., plurality of spaced apart gate segments 706) and the channel layer 108. Dielectric material 712 (e.g., metal oxide or nitride) might be arranged between the gate segments 706. As illustrated in FIG. 7B, each of the plurality of gate segments 706 might extend completely across the width of the transistor 700.

In this embodiment, the plurality of spaced apart gate segments 706 are unevenly spaced apart along the length of the transistor 700 (and the channel layer 108), and each of the plurality of spaced apart gate segments 706 have different lengths. While five gate segments 706 are illustrated in FIGS. 7A and 7B, in other examples, the plurality of gate segments 706 may include less than five (e.g., 2, 3, 4) gate segments or more than five (e.g., 6, 7, 8, 9, 10, or more) gate segments. While the at least one heavily doped region 110 is illustrated in FIG. 7A, in other examples, transistor 700 may include the at least one heavily doped region 310 of FIG. 3, the plurality of heavily doped regions 410 of FIGS. 4A and 4B, or the plurality of heavily doped regions 510 of FIGS. 5A and 5B.

Each gate segment 706 may be biased with a different gate bias to turn off transistor 700 to distribute, in combination with the at least one heavily doped region 110, the channel potential along the channel layer 108 to improve the breakdown voltage of the transistor 700 compared to a transistor including a single gate (e.g., 106 of FIGS. 1A-5B). The bias applied to each gate segment may gradually increase from the lower voltage side of the transistor (e.g., one of source 102 or drain 104) towards the higher voltage side of the transistor (e.g., the other one of source 102 or drain 104). The position, number, and length of gate segments 706 (and the bias applied to each gate segment) and the position and number of heavily doped regions 110 may be selected to provide a desired channel potential distribution across the length of the channel layer 108.

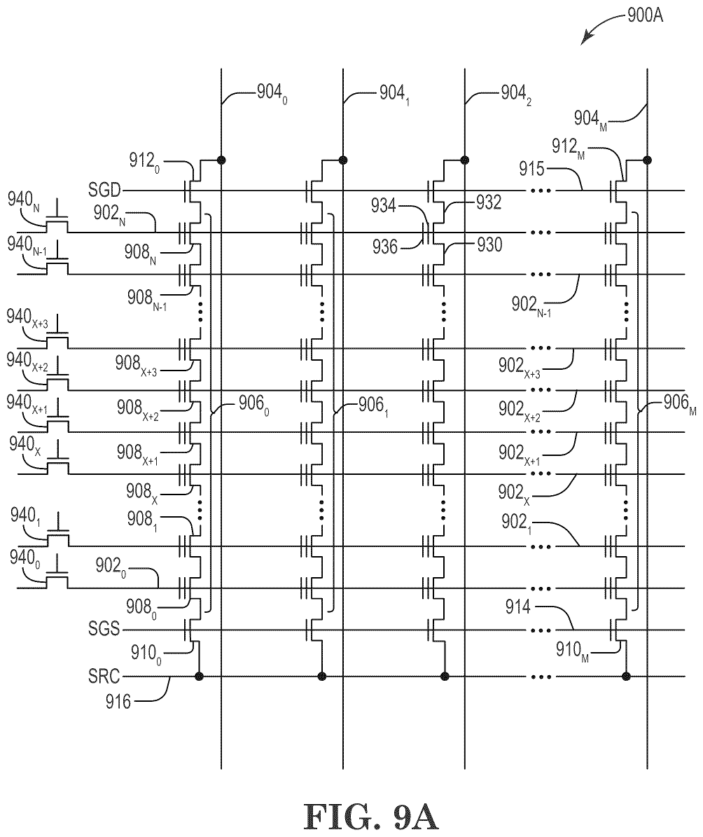

FIG. 8 is a simplified block diagram of a first apparatus, in the form of a memory (e.g., memory device) 800, in communication with a second apparatus, in the form of a processor 830, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 830, e.g., a controller external to the memory device 800, might be a memory controller or other external host device.

Memory device 800 includes an array of memory cells 804 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 8) of at least a portion of array of memory cells 804 are capable of being programmed to one of at least two target data states.

A row decode circuitry 808 and a column decode circuitry 810 are provided to decode address signals. Address signals are received and decoded to access the array of memory cells 804. Memory device 800 also includes input/output (I/O) control circuitry 812 to manage input of commands, addresses and data to the memory device 800 as well as output of data and status information from the memory device 800. An address register 814 is in communication with I/O control circuitry 812 and row decode circuitry 808 and column decode circuitry 810 to latch the address signals prior to decoding. A command register 824 is in communication with I/O control circuitry 812 and control logic 816 to latch incoming commands.

A controller (e.g., the control logic 816 internal to the memory device 800) controls access to the array of memory cells 804 in response to the commands and may generate status information for the external processor 830, i.e., control logic 816 is configured to perform access operations (e.g., sensing operations [which might include read operations and verify operations], programming operations and/or erase operations) on the array of memory cells 804. The control logic 816 is in communication with row decode circuitry 808 and column decode circuitry 810 to control the row decode circuitry 808 and column decode circuitry 810 in response to the addresses. The control logic 816 might include instruction registers 828 which might represent computer-usable memory for storing computer-readable instructions. For some embodiments, the instruction registers 828 might represent firmware. Alternatively, the instruction registers 828 might represent a grouping of memory cells, e.g., reserved block(s) of memory cells, of the array of memory cells 804.

Control logic 816 might also be in communication with a cache register 818. Cache register 818 latches data, either incoming or outgoing, as directed by control logic 816 to temporarily store data while the array of memory cells 804 is busy writing or reading, respectively, other data. During a programming operation (e.g., write operation), data might be passed from the cache register 818 to the data register 820 for transfer to the array of memory cells 804; then new data might be latched in the cache register 818 from the I/O control circuitry 812. During a read operation, data might be passed from the cache register 818 to the I/O control circuitry 812 for output to the external processor 830; then new data might be passed from the data register 820 to the cache register 818. The cache register 818 and/or the data register 820 might form (e.g., might form a portion of) a page buffer of the memory device 800. A page buffer might further include sensing devices (not shown in FIG. 8) to sense a data state of a memory cell of the array of memory cells 804, e.g., by sensing a state of a data line connected to that memory cell. A status register 822 might be in communication with I/O control circuitry 812 and control logic 816 to latch the status information for output to the processor 830.

Memory device 800 receives control signals at control logic 816 from processor 830 over a control link 832. The control signals might include a chip enable CE#, a command latch enable CLE, an address latch enable ALE, a write enable WE#, a read enable RE#, and a write protect WP#. Additional or alternative control signals (not shown) might be further received over control link 832 depending upon the nature of the memory device 800. Memory device 800 receives command signals (which represent commands), address signals (which represent addresses), and data signals (which represent data) from processor 830 over a multiplexed input/output (I/O) bus 834 and outputs data to processor 830 over I/O bus 834.

For example, the commands might be received over input/output (I/O) pins [7:0] of I/O bus 834 at I/O control circuitry 812 and might then be written into command register 824. The addresses might be received over input/output (I/O) pins [7:0] of I/O bus 834 at I/O control circuitry 812 and might then be written into address register 814. The data might be received over input/output (I/O) pins [7:0] for an 8-bit device or input/output (I/O) pins [15:0] for a 16-bit device at I/O control circuitry 812 and then might be written into cache register 818. The data might be subsequently written into data register 820 for programming the array of memory cells 804. For another embodiment, cache register 818 might be omitted, and the data might be written directly into data register 820. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 800 by an external device (e.g., processor 830), such as conductive pads or conductive bumps as are commonly used.

It will be appreciated by those skilled in the art that additional circuitry and signals can be provided, and that the memory device 800 of FIG. 8 has been simplified. It should be recognized that the functionality of the various block components described with reference to FIG. 8 might not necessarily be segregated to distinct components or component portions of an integrated circuit device. For example, a single component or component portion of an integrated circuit device could be adapted to perform the functionality of more than one block component of FIG. 8. Alternatively, one or more components or component portions of an integrated circuit device could be combined to perform the functionality of a single block component of FIG. 8.

Additionally, while specific I/O pins are described in accordance with popular conventions for receipt and output of the various signals, it is noted that other combinations or numbers of I/O pins (or other I/O node structures) might be used in the various embodiments.

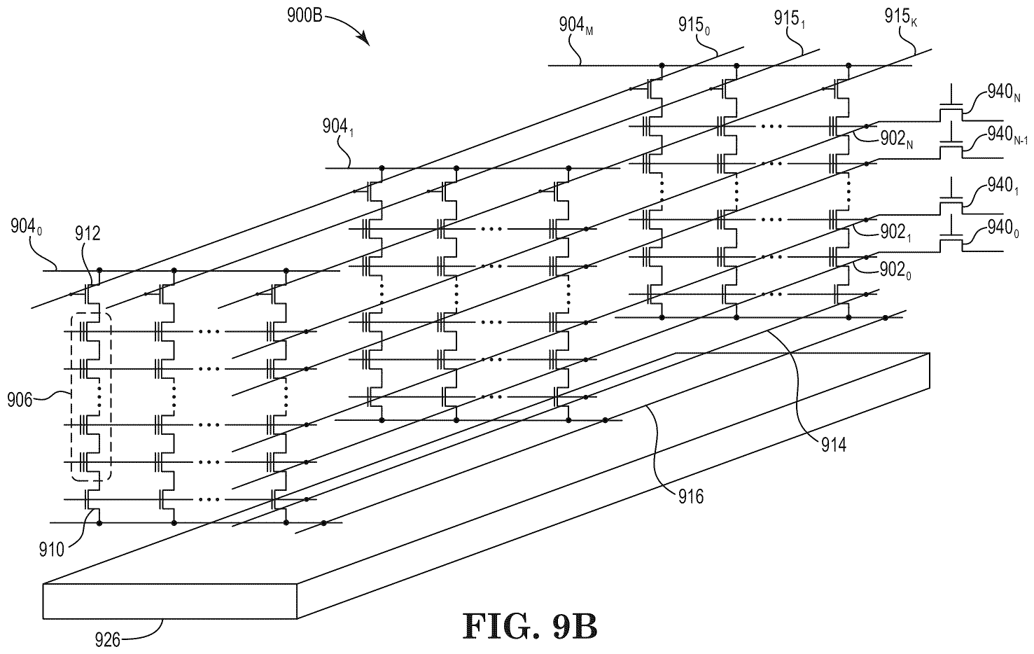

FIG. 9A is a schematic of a portion of an array of memory cells 900A, such as a NAND memory array, as could be used in a memory of the type described with reference to FIG. 8, e.g., as a portion of array of memory cells 804. Memory array 900A includes access lines (e.g., word lines) 902₀ to 902_{N}, and data lines (e.g., bit lines) 904₀ to 904_{M}. The access lines 902 might be connected to global access lines (e.g., global word lines), not shown in FIG. 9A, in a many-to-one relationship. For some embodiments, memory array 900A might be formed over a semiconductor that, for example, might be conductively doped to have a conductivity type, such as a p-type conductivity, e.g., to form a p-well, or an n-type conductivity, e.g., to form an n-well.

Memory array 900A might be arranged in rows (each corresponding to an access line 902) and columns (each corresponding to a data line 904). Each column might include a string of series-connected memory cells (e.g., non-volatile memory cells), such as one of NAND strings 906₀ to 906_{M}. Each NAND string 906 might be connected (e.g., selectively connected) to a common source (SRC) 916 and might include memory cells 908₀ to 908_{N}. The memory cells 908 might represent non-volatile memory cells for storage of data. The memory cells 908₀ to 908_{N} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 908 of each NAND string 906 might be connected in series between a select gate 910 (e.g., a field-effect transistor), such as one of the select gates 910₀ to 910_{M} (e.g., that might be source select transistors, commonly referred to as select gate source), and a select gate 912 (e.g., a field-effect transistor), such as one of the select gates 912₀ to 912_{M} (e.g., that might be drain select transistors, commonly referred to as select gate drain). Select gates 910₀ to 910_{M} might be commonly connected to a select line 914, such as a source select line (SGS), and select gates 912₀ to 912_{M} might be commonly connected to a select line 915, such as a drain select line (SGD). Although depicted as traditional field-effect transistors, the select gates 910 and 912 might utilize a structure similar to (e.g., the same as) the memory cells 908. The select gates 910 and 912 might represent a plurality of select gates connected in series, with each select gate in series configured to receive a same or independent control signal.

A source of each select gate 910 might be connected to common source 916. The drain of each select gate 910 might be connected to a memory cell 908₀ of the corresponding NAND string 906. For example, the drain of select gate 910₀ might be connected to memory cell 908₀ of the corresponding NAND string 906₀. Therefore, each select gate 910 might be configured to selectively connect a corresponding NAND string 906 to common source 916. A control gate of each select gate 910 might be connected to select line 914.

The drain of each select gate 912 might be connected to the data line 904 for the corresponding NAND string 906. For example, the drain of select gate 912₀ might be connected to the data line 904₀ for the corresponding NAND string 906₀. The source of each select gate 912 might be connected to a memory cell 908_{N} of the corresponding NAND string 906. For example, the source of select gate 912₀ might be connected to memory cell 908_{N} of the corresponding NAND string 906₀. Therefore, each select gate 912 might be configured to selectively connect a corresponding NAND string 906 to the corresponding data line 904. A control gate of each select gate 912 might be connected to select line 915.

The memory array in FIG. 9A might be a quasi-two-dimensional memory array and might have a generally planar structure, e.g., where the common source 916, NAND strings 906 and data lines 904 extend in substantially parallel planes. Alternatively, the memory array in FIG. 9A might be a three-dimensional memory array, e.g., where NAND strings 906 might extend substantially perpendicular to a plane containing the common source 916 and to a plane containing the data lines 904 that might be substantially parallel to the plane containing the common source 916.

Typical construction of memory cells 908 includes a data-storage structure 934 (e.g., a floating gate, charge trap, or other structure configured to store charge) that can determine a data state of the memory cell (e.g., through changes in threshold voltage), and a control gate 936, as shown in FIG. 9A. The data-storage structure 934 might include both conductive and dielectric structures while the control gate 936 is generally formed of one or more conductive materials. In some cases, memory cells 908 might further have a defined source/drain (e.g., source) 930 and a defined source/drain (e.g., drain) 932. Memory cells 908 have their control gates 936 connected to (and in some cases form) an access line 902.

Each access line 902₀ to 902_{N} might be connected to one side of the source-drain path of a corresponding transistor 940₀ to 940_{N}, commonly referred to as access line drivers. Each transistor 940₀ to 940_{N} might include transistor 100 of FIGS. 1A and 1B, transistor 300 of FIG. 3, transistor 400 of FIGS. 4A and 4B, transistor 500 of FIGS. 5A and 5B, transistor 600 of FIGS. 6A and 6B, or transistor 700 of FIGS. 7A and 7B. The other side of the source-drain path of each transistor 940₀ to 940_{N} might be selectively connected to a voltage node for biasing each corresponding access line 902₀ to 902_{N} during memory cell programming operations. With the gate (or gate segments) of a transistor 940₀ to 940_{N} biased to turn off the transistor, the channel potential of the transistor is distributed along the channel layer of the transistor as previously described.

A column of the memory cells 908 might be a NAND string 906 or a plurality of NAND strings 906 selectively connected to a given data line 904. A row of the memory cells 908 might be memory cells 908 commonly connected to a given access line 902. A row of memory cells 908 can, but need not, include all memory cells 908 commonly connected to a given access line 902. Rows of memory cells 908 might often be divided into one or more groups of physical pages of memory cells 908, and physical pages of memory cells 908 often include every other memory cell 908 commonly connected to a given access line 902. For example, memory cells 908 commonly connected to access line 902_{N} and selectively connected to even data lines 904 (e.g., data lines 904₀, 904₂, 904₄, etc.) might be one physical page of memory cells 908 (e.g., even memory cells) while memory cells 908 commonly connected to access line 902_{N} and selectively connected to odd data lines 904 (e.g., data lines 904₁, 904₃, 904₅, etc.) might be another physical page of memory cells 908 (e.g., odd memory cells). Although data lines 904₃-904₅ are not explicitly depicted in FIG. 9A, it is apparent from the figure that the data lines 904 of the array of memory cells 900A might be numbered consecutively from data line 904₀ to data line 904_{M}. Other groupings of memory cells 908 commonly connected to a given access line 902 might also define a physical page of memory cells 908. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 902₀ to 902_{N} (e.g., all NAND strings 906 sharing common access lines 902). Unless expressly distinguished, a reference to a page of memory cells herein refers to the memory cells of a logical page of memory cells.

Although the example of FIG. 9A is discussed in conjunction with NAND flash, the embodiments and concepts described herein are not limited to a particular array architecture or structure, and can include other structures (e.g., SONOS or other data storage structure configured to store charge) and other architectures (e.g., AND arrays, NOR arrays, etc.).

FIG. 9B is another schematic of a portion of an array of memory cells 900B as could be used in a memory of the type described with reference to FIG. 8, e.g., as a portion of array of memory cells 804. Like numbered elements in FIG. 9B correspond to the description as provided with respect to FIG. 9A. FIG. 9B provides additional detail of one example of a three-dimensional NAND memory array structure. The three-dimensional NAND memory array 900B might incorporate vertical structures which might include semiconductor pillars where a portion of a pillar might act as a channel region of the memory cells of NAND strings 906. The NAND strings 906 might be each selectively connected to a data line 904₀ to 904_{M} by a select transistor 912 (e.g., that might be drain select transistors, commonly referred to as select gate drain) and to a common source 916 by a select transistor 910 (e.g., that might be source select transistors, commonly referred to as select gate source). Multiple NAND strings 906 might be selectively connected to the same data line 904. Subsets of NAND strings 906 can be connected to their respective data lines 904 by biasing the select lines 915₀ to 915_{K} to selectively activate particular select transistors 912 each between a NAND string 906 and a data line 904. The select transistors 910 can be activated by biasing the select line 914. Each access line 902 might be connected to multiple rows of memory cells of the memory array 900B and might be selectively biased via corresponding transistors 940₀ to 940_{N}. Rows of memory cells that are commonly connected to each other by a particular access line 902 might collectively be referred to as tiers.

The three-dimensional NAND memory array 900B might be formed over peripheral circuitry 926. The peripheral circuitry 926 might represent a variety of circuitry for accessing the memory array 900B. The peripheral circuitry 926 might include complementary circuit elements. For example, the peripheral circuitry 926 might include both n-channel and p-channel transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

### Conclusion

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

What is claimed is:

1. A transistor comprising:
a source;
a drain;
a gate layer;
an undoped or lightly doped channel layer extending between the source and the drain, the channel layer comprising at least one heavily doped region to distribute channel potential along the channel layer; and
a gate dielectric layer between the gate layer and the channel layer.

2. The transistor of claim 1, wherein the at least one heavily doped region extends completely through a thickness of the channel layer.

3. The transistor of claim 1, wherein the at least one heavily doped region extends partially through a thickness of the channel layer.

4. The transistor of claim 1, wherein the at least one heavily doped region extends completely across a width of the channel layer.

5. The transistor of claim 1, wherein the at least one heavily doped region comprises an N+ doped region and the transistor comprises an N-type transistor.

6. The transistor of claim 1, wherein the at least one heavily doped region comprises a P+ doped region and the transistor comprises a P-type transistor.

7. The transistor of claim 1, wherein the channel layer comprises a length within a range between 0.1 and 10 micrometers, a width within a range between 0.1 and 100 micrometers, and a thickness within a range between 1 and 100 nanometers, and
wherein the at least one heavily doped region comprises a length within a range between 10 and 500 nanometers.

8. The transistor of claim 1, wherein the gate layer comprises a plurality of spaced apart gate segments.

9. The transistor of claim 8, wherein the plurality of spaced apart gate segments are evenly spaced apart.

10. The transistor of claim 8, wherein the plurality of spaced apart gate segments are unevenly spaced apart.

11. The transistor of claim 8, wherein a length of each gate segment of the plurality of gate segments are equal.

12. The transistor of claim 8, wherein the plurality of gate segments comprise different lengths.

13. A silicon on insulator or thin-film transistor comprising:
a source;
a drain;
a gate layer;
an undoped or lightly doped channel layer extending between the source and the drain, the channel layer comprising a plurality of heavily doped regions along the channel layer to distribute channel potential along the channel layer; and
a gate dielectric layer between the gate layer and the channel layer.

14. The transistor of claim 13, wherein the plurality of heavily doped regions are evenly spaced apart along the channel layer.

15. The transistor of claim 13, wherein the plurality of heavily doped regions are unevenly spaced apart along the channel layer.

16. The transistor of claim 13, wherein the channel layer comprises at least one of polysilicon, silicon, germanium, silicon-germanium (SiGe), molybdenum disulfide (MoS₂), or a two-dimensional semiconductor.

17. A device comprising:
a silicon on insulator transistor comprising:
a source;
a drain;
a gate layer;
an undoped or lightly doped channel layer extending between the source and the drain, the channel layer comprising a plurality of heavily doped regions along the channel layer to distribute channel potential along the channel layer; and
a gate dielectric layer between the gate layer and the channel layer.

18. The device of claim 17, wherein the channel layer comprises a first semiconductor material and the plurality of heavily doped regions comprise a second semiconductor material different from the first semiconductor material.

19. The device of claim 17, wherein a number of the plurality of heavily doped regions is selected based on a desired breakdown voltage of the transistor.

20. The device of claim 17, further comprising:
an array of memory cells,
wherein the transistor is electrically coupled to an access line of the array of memory cells.
